(19) United States
(12) Patent Application Publication
(10) Pub. No.: US 2016/0078915 A1
(43) Pub. Date: Mar. 17, 2016

(54) RESISTANCE CHANGE MEMORY

(71) Applicant: Akira KATAYAMA, Seoul (KR)

(72) Inventor: Akira KATAYAMA, Seoul (KR)

(21) Appl. No.: 14/644,142

(22) Filed: Mar. 10, 2015

Related U.S. Application Data
(60) Provisional application No. 62/049,066, filed on Sep. 11, 2014.

(51) Int. Cl. G11C 11/16

(52) U.S. Cl. CPC G11C 11/1673; G11C 11/161

(57) ABSTRACT

According to one embodiment, according to one embodiment, a resistance change memory includes a memory cell, a sense amplifier, a control circuit and a storage unit. The memory cell includes a resistance change element. The sense amplifier compares a reference current with a cell current flowing through the memory cell. The control circuit calculates offset information of the reference current. The storage unit is provided for the sense amplifier and stores the offset information. The storage unit corresponds to the sense amplifier one to one.

### CROSS-REFERENCE TO RELATED APPLICATIONS

This application claims the benefit of U.S. Provisional Application No. 62/049,066, filed Sep. 11, 2014, the entire contents of which are incorporated herein by reference.

### FIELD

Embodiments described herein relate generally to a resistance change memory storing data by using a change in a resistance value of a memory element.

### BACKGROUND

In recent years, semiconductor memories using resistance change memories (Magnetoresistive Random Access Memory (MRAM), Phase Change Random Access Memory (PRAM), Resistive Random Access Memory (ReRAM), and the like) as memory devices attract attention.

In a resistance change memory, whether data is “1” or “0” is determined by using the change in the resistance value caused by applying a current (or a voltage).

### BRIEF DESCRIPTION OF THE DRAWINGS

FIG. 1 is a block diagram illustrating the schematic configuration of an MRAM according to a first embodiment;

FIG. 2 is a figure illustrating a configuration of a part of a sense amplifier and a memory array connected to the sense amplifier according to the first embodiment;

FIG. 3 is a circuit diagram illustrating a memory cell according to the first embodiment;

FIG. 4 is a figure illustrating a cross sectional structure of the memory cell according to the first embodiment;

FIG. 5 is a figure illustrating a configuration of a sense amplifier according to the first embodiment;

FIG. 6 is a circuit diagram illustrating a detailed configuration of a sense amplifier according to the first embodiment;

FIG. 7 is a flowchart illustrating operation measuring an offset of the sense amplifier according to the first embodiment;

FIGS. 8 to 10 are figures illustrating a distribution of the number of malfunctioning memory cells measured for each of the sense amplifiers according to the first embodiment;

FIG. 11 is a figure illustrating a distribution of the number of malfunctioning memory cells and an offset measured for each of the sense amplifiers according to the first embodiment;

FIG. 12 is a circuit diagram illustrating a detailed configuration of a sense amplifier according to a second embodiment; and

FIG. 13 is a figure illustrating a configuration of a sense amplifier according to a modification.

### DETAILED DESCRIPTION

Hereinafter, a resistance change memory according to an embodiment will be explained with reference to the drawings. In the explanation below, constituent elements having the same functions and configurations will be denoted with the same reference numerals, and they will be explained only when necessary. Each of the following embodiments is shown to present an example of a device and a method for carrying out the technical concept of the embodiment, and it is to be understood that the materials, the shapes, the structures, the arrangements, and the like of the constituent components are not limited to those shown below.

In general, according to one embodiment, a resistance change memory includes a memory cell, a sense amplifier, a control circuit and a storage unit. The memory cell includes a resistance change element. The sense amplifier compares a reference current with a cell current flowing through the memory cell. The control circuit calculates offset information of the reference current. The storage unit is provided for the sense amplifier and stores the offset information. The storage unit corresponds to the sense amplifier one to one.

In the explanation about the embodiment below, an MRAM is used as an example of the resistance change memory.

### First Embodiment

The MRAM according to the first embodiment will be explained.

### 1. Configuration of MRAM

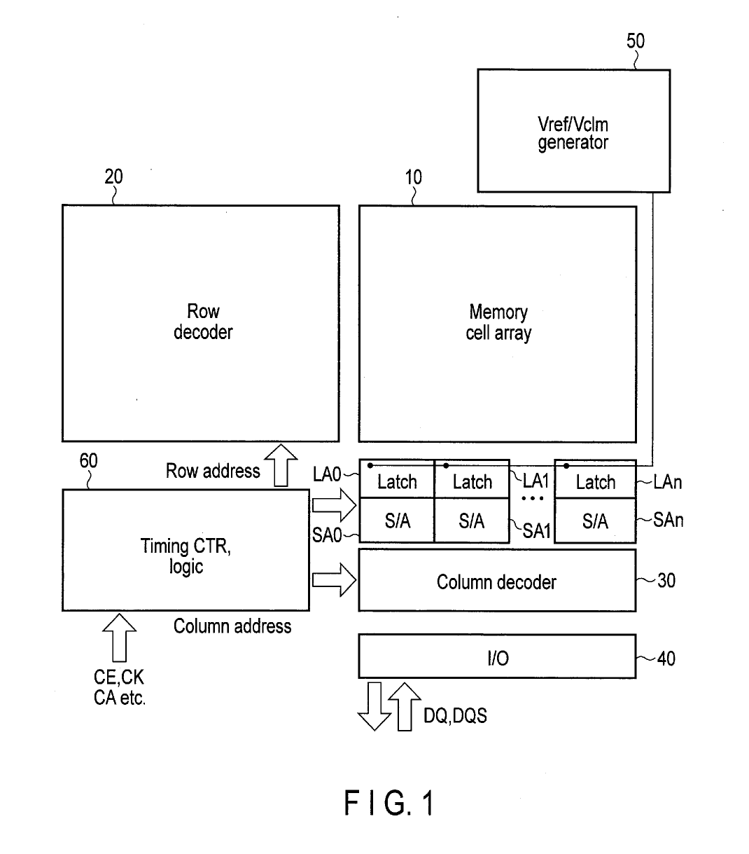

FIG. 1 is a block diagram illustrating the schematic configuration of the MRAM according to the first embodiment.

The MRAM according to the present embodiment includes a memory cell array 10, a row decoder 20, sense amplifiers SA0, . . . , SAn, a column decoder 30, an input and output circuit 40, a voltage generation circuit 50, and a controller 60.

The memory cell array 10 includes memory cells arranged in a matrix form. In this case, the memory cell includes a magnetoresistive effect element, for example, an MTJ (magnetic tunnel junction) element as a resistance change element. The detailed configuration of the memory cell will be explained later.

The row decoder 20 selects any one of word lines based on a row address.

The sense amplifiers SA0 to SAn are provided for each of the memory cells in the memory cell array 10. The sense amplifiers SA0 to SAn read data stored in the memory cells. In a case of, for example, a current detection method, the sense amplifier 12 compares the cell current flowing through the selected memory cell via the bit line and the reference current flowing through the reference resistance via the reference bit line, thereby detecting and amplifying data stored in the selected memory cell based on the relationship of the magnitudes thereof. Each of the sense amplifiers SA0 to SAn includes a latch LA. In other words, a latch LA is provided for each sense amplifier. The details of the latch LA will be explained later.

The column decoder 30 selects any one of bit lines based on a column address. The input and output circuit 40 inputs and outputs data DQ, DQS to/from the outside. The voltage generation circuit 50 generates various kinds of voltages such as a reference voltage Vref and a clamp voltage Vclm.

The controller (including a timing controller and a logic circuit) 60 centrally controls operations of the row decoder 20, the sense amplifiers SA0 to SAn, the column decoder 30, the input and output circuit 40, and the voltage generation circuit 50. The controller 60 receives an address (including a row address RA and a column address CA), a control signal, for example, a clock CLK and a command. Then, the controller 60 provides various kinds of control signals and various kinds of voltages to the row decoder 20, the sense amplifiers SA0 to SAn, the column decoder 30, the input and output circuit 40, and the voltage generation circuit 50, thus controlling operations of these circuits.

1.1 Configurations of Sense Amplifier and Memory Cell Array

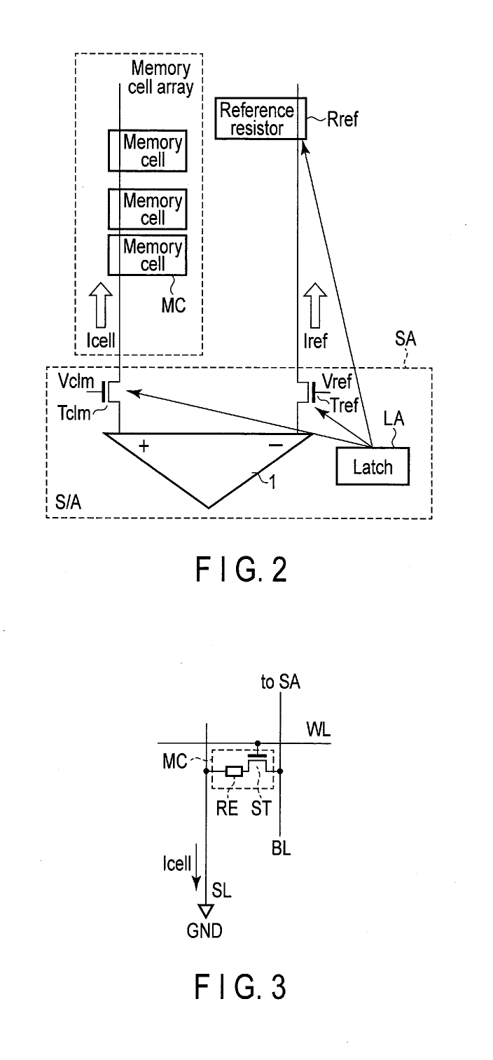

FIG. 2 is a figure illustrating a configuration of a part of a sense amplifier and a memory array connected to the sense amplifier according to the first embodiment. Hereinafter, each of the sense amplifiers SA0 to SAn will be denoted as a sense amplifier SA.

The sense amplifier SA includes a sense unit 1, a latch LA, and n-channel MOS field effect transistors (hereinafter referred to as nMOS transistors) Tclm, Tref. The sense amplifier SA senses the magnitudes of a cell current Icell and a reference current Iref flowing through a first input terminal (+) and a second input terminal (−), respectively. The memory cells MC are connected to the first input terminal of the sense amplifier SA via the nMOS transistor Tclm. A reference resistance Rref is connected to the second input terminal of the sense amplifier SA via the nMOS transistor Tref. The reference resistance Rref is made of a resistance material such as a diffusion layer of a semiconductor substrate.

The sense amplifier SA includes a latch LA. This latch LA is provided for each sense amplifier. The latch LA stores offset information which is set based on the direction and the amount of offset of currents flowing through the first and second input terminals when the currents are sensed. The offset information is information which is set based on the direction and the amount of offset of the cell current Icell and the reference current Iref sensed by the sense amplifier SA. The offset information will be explained later in detail. The latch LA includes, for example, cells of SRAM (static RAM). The latch LA may be made of other volatile memory devices or nonvolatile memory devices. The nonvolatile memory device may be, for example, the memory cell according to the present embodiment, and more specifically, the nonvolatile memory device may be the memory cell having the MTJ element.

The cell current Icell flows from the first input terminal of the sense amplifier SA to the memory cell MC. When the magnetization of the MTJ element in the memory cell MC is in the parallel state, a current Ip flows as a cell current. When the magnetization of the MTJ element in the memory cell MC is in the antiparallel state, a current Tap flows as a cell current. A clamp voltage Vclm is input into the gate of the nMOS transistor Tclm. The nMOS transistor Tclm limits the cell current Icell in accordance with the clamp voltage Vclm so that read disturb does not occur in the memory cell MC. The clamp voltage Vclm is provided by the voltage generation circuit 50.

The reference current Iref flows from the second input terminal of the sense amplifier SA to the reference resistance Rref. The reference voltage Vref is input into the gate of the nMOS transistor Tref. The nMOS transistor Tref adjusts the reference current Iref in accordance with the reference voltage Vref. The reference current Iref is adjusted to be a current which is midway between the current Ip and the current Iap. The reference voltage Vref is provided by the voltage generation circuit 50.

The latch LA stores offset information which is set based on the direction and the amount of offset of currents flowing through the first and second input terminals when the currents are sensed. The sense amplifier SA controls at least one of the nMOS transistor Tref, the nMOS transistor Tclm, and reference resistance Rref in accordance with the offset information. According to this control, the reference current Iref or the cell current Icell is adjusted, so that the margin during reading of the sense amplifier SA can be improved.

1.2 Configuration of Memory Cell

Now, the detailed structure of the memory cell MC in the memory cell array 10 will be explained.

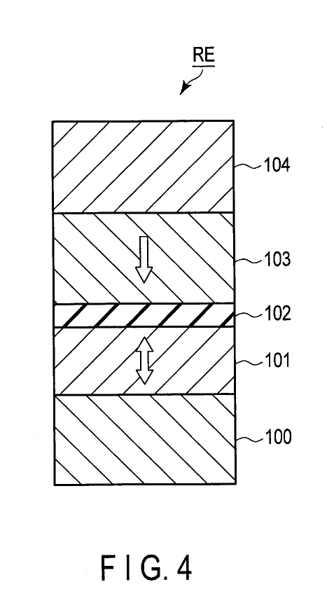

FIG. 3 is a circuit diagram illustrating the memory cell MC. FIG. 4 is a figure illustrating a cross sectional structure of the memory cell.

As shown in FIG. 3, the memory cell MC is connected between the bit line BL and the source line SL. The memory cell MC comprises a resistance change element such as an MTJ (magnetic tunnel junction) element RE and a selection transistor ST. The selection transistor ST comprises, for example, an n-channel MOS field effect transistor.

One end of the MTJ element RE is connected to the bit line BL, and the other end of the MTJ element RE is connected to the drain of the selection transistor ST. The source of the selection transistor ST is connected to the source line SL. Further, the gate of the selection transistor ST is connected to the word line WL.

Subsequently, an example structure of an MTJ element RE included in the memory cell MC will be explained. FIG. 4 is a cross sectional view illustrating the MTJ element RE.

The MTJ element RE includes a lower electrode 100, a storage layer (which may be hereinafter referred to as a free layer) 101, a nonmagnetic layer (which may be hereinafter referred to as a tunnel barrier layer) 102, a reference layer (which may be hereinafter referred to as a fixed layer) 103, and an upper electrode 104, which are stacked in order. The order of stacking of the storage layer 101 and the reference layer 103 may be opposite.

The storage layer 101 and the reference layer 103 are made of a ferromagnetic material. The tunnel barrier layer 102 may be, for example, an insulating material such as MgO.

The storage layer 101 and the reference layer 103 each have perpendicular magnetic anisotropy, and their easy magnetization directions are perpendicular directions. The magnetization directions of the storage layer 101 and the reference layer 103 may be in-plane directions.

The magnetization direction of the storage layer 101 is variable (can be reversed). The magnetization direction of the reference layer 103 is invariable (fixed). The reference layer 103 is set to have sufficiently higher perpendicular magnetic anisotropic energy than the storage layer 101. The magnetic anisotropy can be set by adjusting the material configuration and the film thickness. Thus, a magnetization inversion current for the storage layer 101 is lower, and a magnetization inversion current for the reference layer 103 is higher than that for the storage layer 101. As a result, it is possible to obtain the MTJ element RE that comprises the storage layer 101 variable in magnetization direction and the reference layer 103 invariable in magnetization direction for a predetermined write current.

According to the present embodiment, a spin-transfer torque writing method is used so that a write current is directly passed through the MTJ element RE, and the magnetization state of the MTJ element RE is controlled by this write current. The MTJ element RE can take one of a low-resistance state and a high-resistance state depending on whether the magnetizations of the storage layer 101 and the reference layer 103 are parallel or antiparallel.

If a write current flowing from the storage layer 101 to the reference layer 103 is passed through the MTJ element RE, the magnetizations of the storage layer 101 and the reference layer 103 are parallel. In this parallel state, the resistance value of the MTJ element RE is lowest, and the MTJ element RE is set to the low-resistance state. The low-resistance state of the MTJ element RE is defined as, for example, data “0”.

On the other hand, if a write current flowing from the reference layer 103 to the storage layer 101 is passed through the MTJ element RE, the magnetizations of the storage layer 101 and the reference layer 103 are antiparallel. In this antiparallel state, the resistance value of the MTJ element RE is highest, and the MTJ element RE is set to the high-resistance state. The high-resistance state of the MTJ element RE is defined as, for example, data “1”.

Consequently, the MTJ element RE can be used as a storage element capable of storing one-bit data (binary data). Any resistance state of the MTJ element RE and any allocation of data can be set.

When data is read from the MTJ element RE, a read voltage is applied to the MTJ element RE, and the resistance value of the MTJ element RE is detected in accordance with a read current flowing through the MTJ element RE at the moment. This read voltage is set to a value sufficiently lower than a threshold at which the magnetization is reversed by spin-transfer torque.

1.3 Configuration of Sense Amplifier According to the First Embodiment

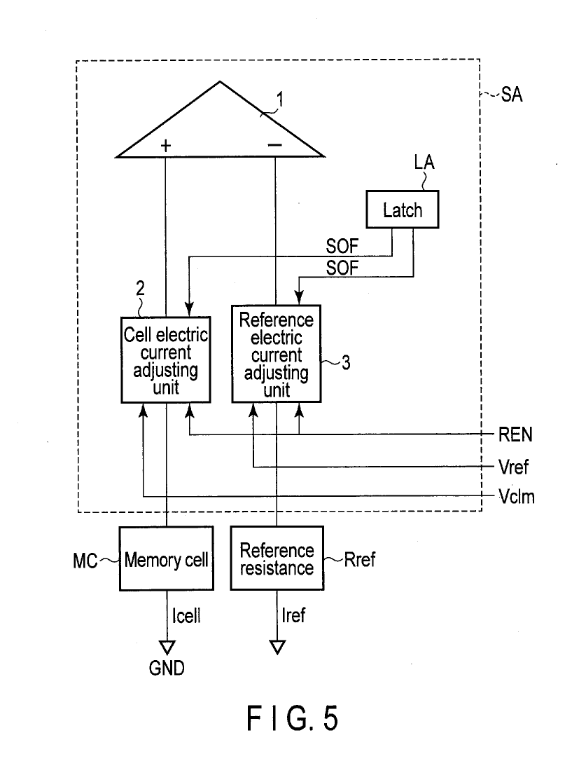

FIG. 5 is a figure illustrating a configuration of a sense amplifier according to the first embodiment.

As shown in FIG. 5, the sense amplifier SA includes a sense unit 1, a cell current adjusting unit 2, a reference current adjusting unit 3, and a latch LA. The first input terminal (+) of the sense amplifier SA is connected to the cell current adjusting unit 2, and further, the cell current adjusting unit 2 is connected to one end of the memory cell MC. The other end of the memory cell MC receives a reference voltage (for example, ground potential) GND. The second input terminal (−) of the sense amplifier SA is connected to the reference current adjusting unit 3, and further, the reference current adjusting unit 3 is connected to one end of the reference resistance Rref. The other end of the reference resistance Rref receives the reference voltage GND. The latch LA outputs the offset information SOF to the cell current adjusting unit 2 and the reference current adjusting unit 3.

The cell current adjusting unit 2 and the reference current adjusting unit 3 receive a read-enable signal REN. The read-enable signal REN is a signal for controlling the read operation of the sense amplifier SA. The cell current adjusting unit 2 receives the clamp voltage Vclm, and the reference current adjusting unit 3 receives the reference voltage Vref. The clamp voltage Vclm is a voltage for adjusting the cell current Icell, and the reference voltage Vref is a voltage for adjusting the reference current Iref.

The sense unit 1 compares the cell current Icell flowing to the first input terminal (+) and the reference current Iref flowing to the second input terminal (−), and outputs the comparison result. The latch LA stores offset information SOF of the first and second input terminals when the current is sensed.

The cell current adjusting unit 2 adjusts the cell current Icell flowing to the memory cell MC in accordance with the offset information SOF stored in the latch LA. The reference current adjusting unit 3 adjusts the reference current Iref flowing to the reference resistance Rref in accordance with the offset information SOF stored in the latch LA. The adjustment may be performed by both of the cell current adjusting unit 2 and the reference current adjusting unit 3, or may be performed by any one of the cell current adjusting unit 2 and the reference current adjusting unit 3. Therefore, when the reference current Iref is adjusted to a value midway between the current Ip and the current Iap, the margin during reading of the sense amplifier SA can be improved.

1.3.1 Detailed Configuration of Sense Amplifier

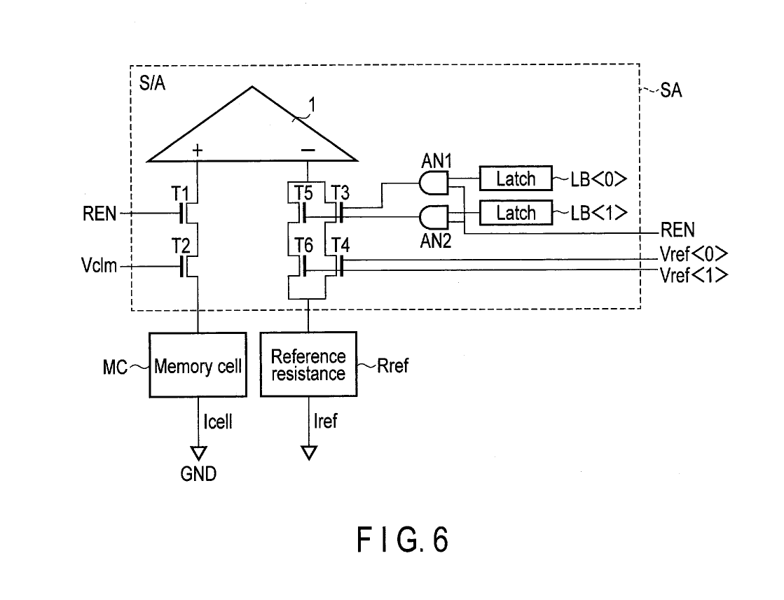

FIG. 6 is a circuit diagram illustrating a detailed configuration of the sense amplifier according to the first embodiment.

As shown in FIG. 6, the sense amplifier SA includes a sense unit 1, nMOS transistors T1, T2, . . . , T6, logical multiplication circuits AN1, AN2, a latch LB<0>, and a latch LB<1>. The first input terminal (+) of the sense unit 1 is connected to one end of the memory cell MC via the nMOS transistors T1, T2, and the other end of the memory cell MC receives the reference voltage GND. The nMOS transistors T3, T4 connected in series and the nMOS transistors T5, T6 connected in series are connected in parallel between the second input terminal (−) of the sense unit 1 and one end of the reference resistance Rref. Further, the other end of the reference resistance Rref receives the reference voltage GND.

The output of the latch LB<0> is input into the first input terminal of the logical multiplication circuit AN1. The output of the latch LB<1> is input into the first input terminal of the logical multiplication circuit AN2. The read-enable signal REN is input into the second input terminals of the logical multiplication circuits AN1, AN2. The output of the logical multiplication circuit AN1 is input into the gate of the nMOS transistor T3. The output of the logical multiplication circuit AN2 is input into the gate of the nMOS transistor T5. The gate of the nMOS transistor T4 receives a reference voltage Vref<0>, and the gate of the nMOS transistor T6 receives a reference voltage Vref<1>.

The gate of the nMOS transistor T1 receives the read-enable signal REN, and the gate of the nMOS transistor T2 receives the clamp voltage Vclm.

Subsequently, operation of the sense amplifier as shown in FIG. 6 will be explained.

The latch LB<0> and the latch LB<1> store the offset information of the sense amplifier SA. For example, as the offset information, the latch LB<0> stores “High (H)”, and the latch LB<1> stores “Low (L)”.

When “H” is input as a read-enable signal REN for permitting reading, the logical multiplication circuit AN1 outputs “H” because the latch LB<0> stores “H”. Therefore, the nMOS transistor T3 attains the ON state. Since the latch LE<1> stores “L”, the logical multiplication circuit AN2 outputs “L”. Accordingly, the nMOS transistor T5 attains the OFF state.

The gate of the nMOS transistor T4 receives the reference voltage Vref<0>, and the gate of the nMOS transistor T6 receives the reference voltage Vref<1>.

When the nMOS transistor T3 attains the ON state, an current path is formed in the nMOS transistors T3, T4, and the reference current Iref flows to the reference resistance Rref via the transistors T3, T4. At this occasion, the gate of the nMOS transistor T4 receives the reference voltage Vref<0>, and therefore, the reference current Iref is a current adjusted according to the reference voltage Vref<0>. On the other hand, the nMOS transistor T5 attains the OFF state, and therefore, a current path is not formed in the transistors T5, T6, and no current flows.

For example, when the latch LB<0> stores “L” and the latch LB<1> stores “H”, then the operation is as follows. When “H” is input as the read-enable signal REN, the logical multiplication circuit AN1 outputs “L” because the latch LB<0> stores “L”. Therefore, the nMOS transistor T3 attains the OFF state. On the other hand, since the latch LB<1> stores “H”, the logical multiplication circuit AN2 outputs “H”. Therefore, the nMOS transistor T5 attains the ON state.

When the nMOS transistor T5 attains the ON state, a current path is formed in the nMOS transistors T5, T6, and the reference current Iref flows to the reference resistance Rref via the transistors T5, T6. At this occasion, the gate of the nMOS transistor T6 receives the reference voltage Vref<1>, and therefore, the reference current Iref is a current adjusted according to the reference voltage Vref<1>. On the other hand, the nMOS transistor T3 attains the OFF state, and therefore, a current path is not formed in the transistors T3, T4, and no current flows.

According to such operation, any one of the reference current adjusted by the reference voltage Vref<0> and the reference current adjusted by the reference voltage Vref<1> can be selected in accordance with the offset information stored in the latch LB<0> and the latch LB<1>. Therefore, when the reference current Iref is adjusted to a value midway between the current Ip and the current Iap, the margin during reading of the sense amplifier SA can be improved.

In the explanation about this case above, the reference current Iref is adjusted. Alternatively, the cell current Icell may be adjusted. In the latter case, the configuration for adjusting the reference current may be used for the cell current. In this example, a single reference resistance is provided for a single sense amplifier. Alternatively, a single reference resistance may be provided for sense amplifiers, so that the reference resistance is shared by sense amplifiers.

1.3.2 Evaluation of Offset of Sense Amplifier

Subsequently, the measurement and evaluation of the offset in the sense amplifier SA will be explained. Hereinafter, an example of a method for measuring the offset of each sense amplifier will be given.

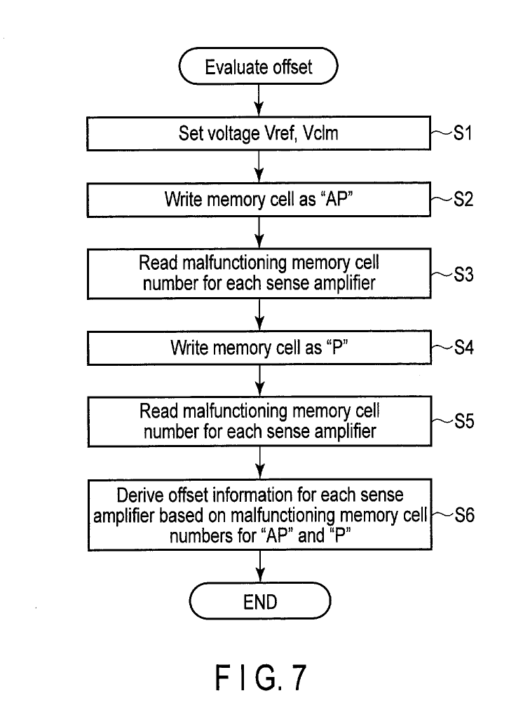

FIG. 7 is a flowchart illustrating operation of measuring the offset of the sense amplifier. The following operation is performed by the sense amplifier SA under the control of the controller. Alternatively, the following operation may be performed by the sense amplifier SA under the control of an external tester.

In the sense amplifier as shown in FIG. 2, first, the reference voltage Vref and the clamp voltage Vclm are provided to the sense amplifier SA (step S1). Subsequently, a writing operation is performed on the memory cell MC, and the magnetization of the MTJ element is caused to be in antiparallel state (step S2). This memory cell will be hereinafter referred to as an AP cell. Subsequently, a malfunctioning memory cell number (fail bit count; FBC) is read for each sense amplifier (step S3).

Subsequently, a writing operation is performed on the memory cell MC, and the magnetization of the MTJ element is caused to be in a parallel state (step S4). This memory cell will be hereinafter referred to as a P cell. Subsequently, a malfunctioning memory cell number is read for each sense amplifier (step S5).

Subsequently, the offset information about the sense amplifier SA is derived based on the malfunctioning memory cell numbers for the AP cell and the P cell (step S6).

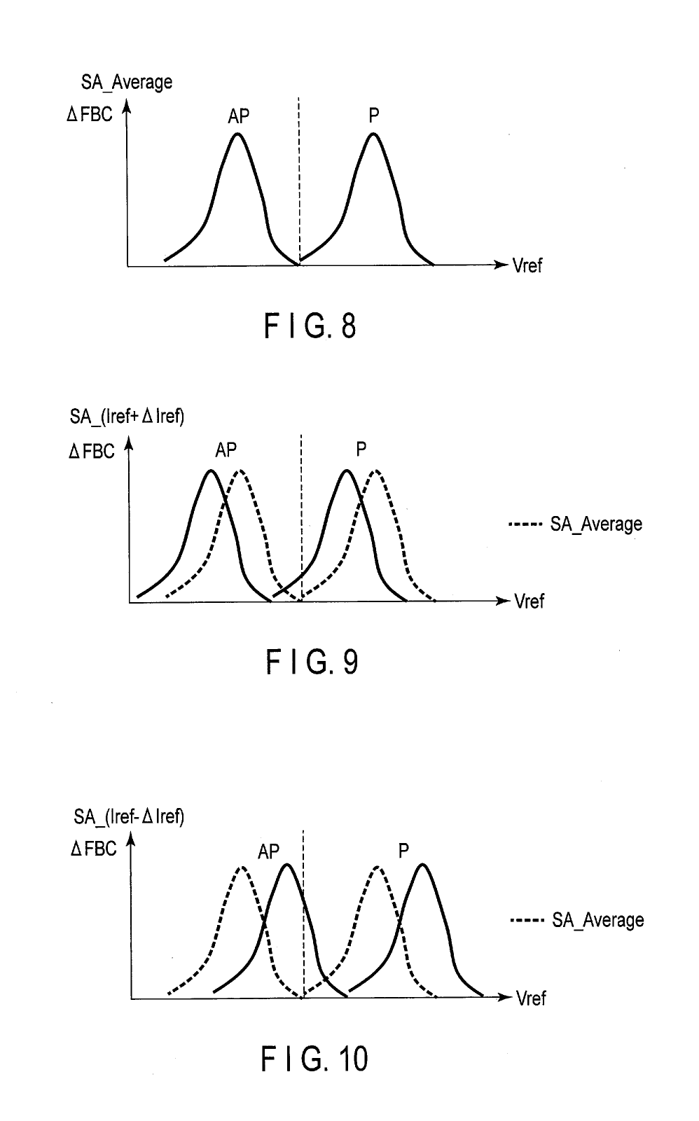

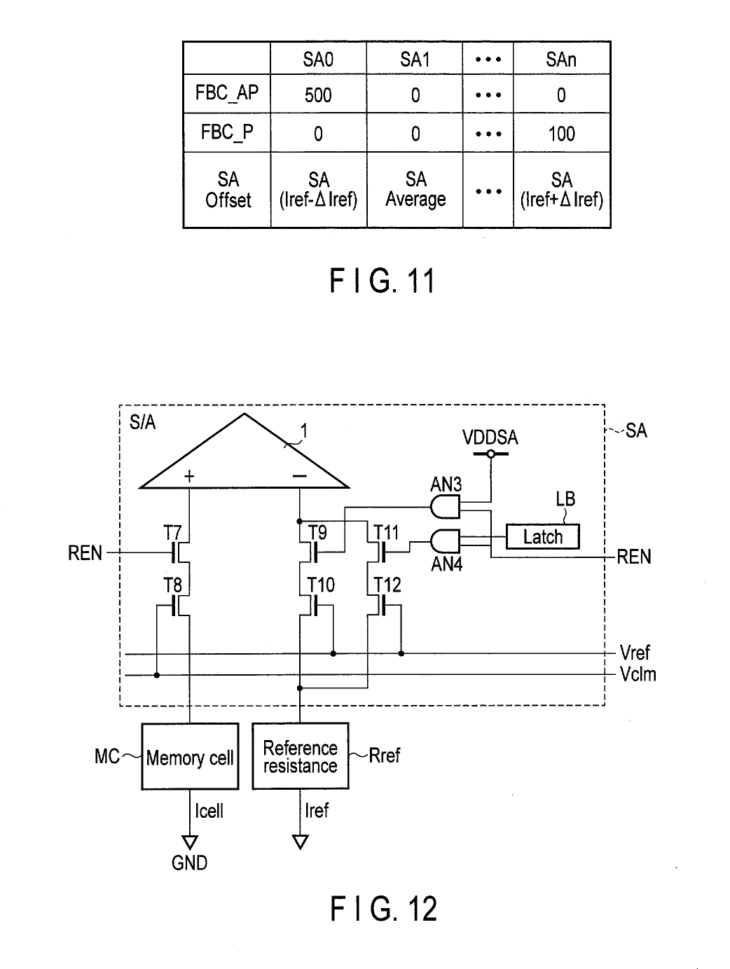

Hereinafter, in step S6, a method for evaluating the direction and the amount of the offset based on the malfunctioning memory cell numbers for the AP cell and the P cell will be explained in more detail. FIGS. 8 to 10 are figures illustrating distributions of malfunctioning memory cell numbers measured for each sense amplifier by applying a certain reference voltage Vref. FIG. 11 is a figure illustrating the offset and the malfunctioning memory cell number measured for each sense amplifier.

As shown in FIG. 8, in the sense amplifier SA1, the malfunctioning memory cell numbers of the AP cell and the P cell with respect to the certain level of reference voltage Vref are low. In such case, the offset of the sense amplifier SA1 can be evaluated as being small.

As shown in FIG. 10, in the sense amplifier SA0, the malfunctioning memory cell number of the AP cell with respect to the certain level of reference voltage Vref is high. In this case, the offset can be evaluated as existing in the direction “Iref−ΔIref”.

As shown in FIG. 9, in the sense amplifier SAn, the malfunctioning memory cell number of the P cell with respect to the certain level of reference voltage Vref is high. In this case, the offset can be evaluated as existing in the direction “Iref+ΔIref”.

As shown in FIG. 11, in the sense amplifier SA0, the malfunctioning memory cell number of the AP cell is 500, and in this case, the offset amount ΔIref can be evaluated as being large. In the sense amplifier SA1, the malfunctioning memory cell numbers are zero, and in this case, the offset can be evaluated as hardly existing. In the sense amplifier SAn, the malfunctioning memory cell number of the P cell is 100, and in this case, the offset amount ΔIref can be evaluated as being a medium level.

The directions and amounts of the offsets thus derived are set in multiple states, and the multiple states which have been set are stored to the latch LA as single- or multi-bit information (offset information). For example, in the first embodiment as shown in FIG. 6, two-bit offset information is stored to the latch.

### 2. Effect of Embodiment

When the sense amplifier senses a current with the first and second input terminals, there may be an offset in the first and second input terminals. This offset degrades the reading margin when data are read from the memory cell.

Therefore, in the present embodiment, the offset information is stored to the storage unit provided in the sense amplifier (for example, a latch), and during sensing, the reference current (or the cell current) is adjusted based on the offset information. Therefore, when the reference current is adjusted to a value midway between the current of the P cell and the current of the AP cell, the margin during reading of the sense amplifier SA can be improved.

### Second Embodiment

In the second embodiment, another example of a detailed configuration of a sense amplifier will be explained. The reference voltage Vref is constant, and the transistor arranged in the current path of the reference current Iref is controlled to attain the ON state or the OFF state, whereby the reference current is adjusted. Except for the configuration and operation explained below, the configuration and operation of the resistance change memory according to the second embodiment are the same as those of the first embodiment.

### 1. Detailed Configuration of Sense Amplifier

FIG. 12 is a circuit diagram illustrating a detailed configuration of the sense amplifier according to the second embodiment.

As shown in the figure, a sense amplifier SA includes a sense unit 1, nMOS transistors T7, T8, . . . , T12, logical multiplication circuits AN3, AN4, and a latch LB. The first input terminal (+) of the sense unit 1 is connected to one end of the memory cell MC via nMOS transistors T7, T8, and the other end of the memory cell MC receives a reference voltage GND. The nMOS transistors T9, T10 connected in series and the nMOS transistors T11, T12 connected in series are connected in parallel between the second input terminal (−) of the sense unit 1 and one end of the reference resistance Rref. Further, the other end of the reference resistance Rref receives the reference voltage GND.

The first input terminal of the logical multiplication circuit AN3 receives a power supply voltage VDDSA. The output of the latch LB is input into the first input terminal of the logical multiplication circuit AN4. A read-enable signal REN is input into the second input terminal of the logical multiplication circuits AN3, AN4. The output of the logical multiplication circuit AN3 is input into the gate of the nMOS transistor T9. The output of the logical multiplication circuit AN4 is input into the gate of the nMOS transistor T11. The gates of the nMOS transistors T10, T12 receive the reference voltage Vref.

The read-enable signal REN is input into the gate of the nMOS transistor T7, and the gate of the nMOS transistor T8 receives a clamp voltage Vclm.

Subsequently, operation of the sense amplifier as shown in FIG. 12 will be explained.

The latch LB stores offset information about the sense amplifier SA. For example, the latch LB stores “H” as the offset information.

When “H” is input as the read-enable signal REN, “H” is input into the first input terminal of the logical multiplication circuit AN3, and therefore, “H” is output from the logical multiplication circuit AN3. Accordingly, the nMOS transistor T9 attains the ON state. Since the latch LB stores “H”, the logical multiplication circuit AN4 outputs “H”. Therefore, the nMOS transistor T11 attains the ON state.

The gates of the nMOS transistors T10, T12 receive the reference voltage Vref.

When the nMOS transistors T9, T11 attain the ON state, current paths are formed through the nMOS transistors T9, T10 and through the nMOS transistors T11, T12, so that the reference current Iref flows to the reference resistance Rref via the current path of the transistors T9, T10 and the current path of the transistors T11, T12. As a result, the reference current Iref is adjusted to a first current value.

For example, when the latch LB stores “L” as the offset information, then the operation is as follows. When “H” is input as the read-enable signal REN, the logical multiplication circuit AN3 outputs “H”. Therefore, the nMOS transistor T9 attains the ON state. On the other hand, since the latch LB stores “L”, the logical multiplication circuit AN4 outputs “L”. Therefore, the transistor T11 attains the OFF state.

When the nMOS transistor T9 attains the ON state, a current path is formed in the nMOS transistors T9, T10. On the other hand, the nMOS transistor T11 is in the OFF state, and therefore, a current path is not formed in the nMOS transistors T11, T12, and no current flows. Therefore, the reference current Iref flows to the reference resistance Rref via the current path of the nMOS transistors T9, T10. As a result, the reference current Iref is adjusted to a second current value different from the first current value.

When the ratio between the channel width W1 of the transistors T9, T10 and the channel width W2 of the transistors T11, T12 is changed, the reference current Iref can be adjusted to a third current value different from the first and second current values.

In the explanation about this case, for example, the reference current Iref is adjusted. Alternatively, the cell current Icell may be adjusted. In the latter case, the configuration for adjusting the reference current may be used for the cell current.

### 2. Advantages of Embodiment

In the second embodiment, there may be only one latch storing offset information. Therefore, the size of the area required for forming the sense amplifier can be reduced as compared with the first embodiment. The other advantages of the second embodiment are the same as those of the first embodiment.

### Modification and Others

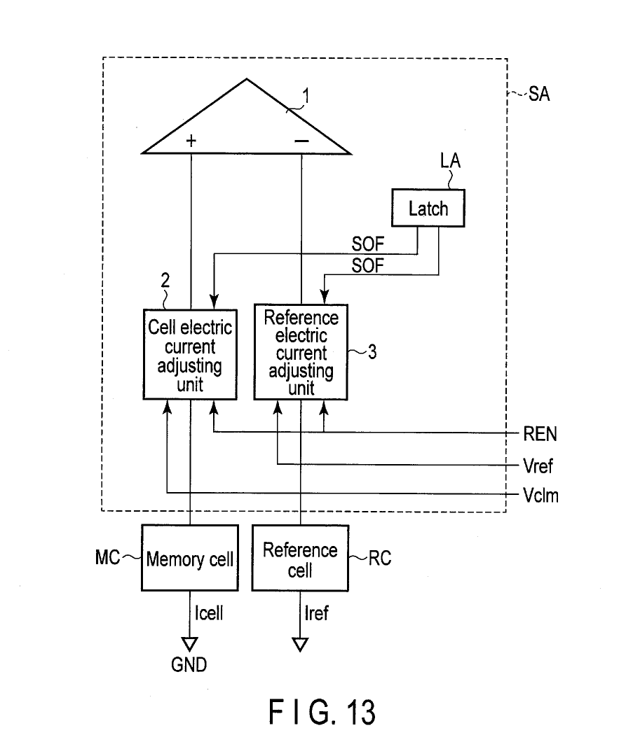

In the explanation about the first embodiment given above, the reference resistance Rref is used to generate the reference current Iref. Alternatively, as shown in FIG. 13, the present technique can also be applied to a case where the reference cell RC is used instead of the reference resistance. The reference cell RC has the same structure as that of the memory cell MC, and is formed according to the same manufacturing steps. The other advantages and configuration thereof are the same as those of the first embodiment.

In the explanation about the embodiments, the MRAM using the magnetoresistive effect element as the resistance change memory has been explained as an example. However, the embodiments are not limited thereto. The embodiments can be applied to various types of semiconductor storage devices regardless of whether they refer to volatile memory or nonvolatile memory. For example, the embodiments can also be applied to resistance change memories of the same type as MRAM, such as an ReRAM (Resistive Random Access Memory) and a PCRAM (Phase-Change Random Access Memory).

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A resistance change memory comprising:
a memory cell comprising a resistance change element;
a sense amplifier which compares a reference current with a cell current flowing through the memory cell;
a control circuit which calculates offset information of the reference current; and
a storage unit which is provided for the sense amplifier and stores the offset information, the storage unit corresponding to the sense amplifier one to one.

2. The resistance change memory according to claim 1, wherein the control circuit controls the reference current in accordance with the offset information stored in the storage unit.

3. The resistance change memory according to claim 1, wherein the control circuit controls the cell current in accordance with the offset information stored in the storage unit.

4. The resistance change memory according to claim 1 further comprising:
a first circuit which outputs a first current as the reference current; and
a second circuit which outputs a second current as the reference current,
wherein the control circuit activates at least any one of the first and second circuits in accordance with the offset information.

5. The resistance change memory according to claim 1 further comprising:
a third circuit which outputs a third current as the cell current; and
a fourth circuit which outputs a fourth current as the cell current,
wherein the control circuit activates at least any one of the third and fourth circuits in accordance with the offset information.

6. The resistance change memory according to claim 1, wherein the offset information is set based on a direction and an amount of offset between the cell current and the reference current in the sense amplifier.

7. The resistance change memory according to claim 1, wherein the reference current is a current flowing through a diffusion layer of a semiconductor substrate.

8. The resistance change memory according to claim 1, wherein the reference current is a current flowing through the memory cell comprising the resistance change element.

9. The resistance change memory according to claim 1, wherein the storage unit comprises a latch.

10. The resistance change memory according to claim 1, wherein the resistance change element comprises a magnetic tunnel junction (MTJ) element.

11. The resistance change memory according to claim 1, wherein the storage unit comprises a volatile memory.

12. A resistance change memory comprising:
a memory cell comprising a resistance change element;
a sense amplifier which compares a reference current with a cell current flowing through the memory cell; and
a nonvolatile storage unit which is provided for the sense amplifier and stores an offset information of the reference current, the nonvolatile storage unit corresponding to the sense amplifier one to one.

13. The resistance change memory according to claim 12, wherein the sense amplifier controls the reference current in accordance with the offset information stored in the nonvolatile storage unit.

14. The resistance change memory according to claim 12, wherein the sense amplifier controls the cell current in accordance with the offset information stored in the nonvolatile storage unit.

15. The resistance change memory according to claim 12, further comprising:
a first circuit which outputs a first current as the reference current; and
a second circuit which outputs a second current as the reference current,
wherein the sense amplifier activates at least any one of the first and second circuits in accordance with the offset information.

16. The resistance change memory according to claim 12 further comprising:
a third circuit which outputs a third current as the cell current; and
a fourth circuit which outputs a fourth current as the cell current,
wherein the sense amplifier activates at least any one of the third and fourth circuits in accordance with the offset information.

17. The resistance change memory according to claim 12, wherein the offset information is set based on a direction and an amount of offset between the cell current and the reference current in the sense amplifier.

18. The resistance change memory according to claim 12, wherein the reference current is a current flowing through a diffusion layer of a semiconductor substrate.

19. The resistance change memory according to claim 12, wherein the reference current is a current flowing through the memory cell comprising the resistance change element.

20. The resistance change memory according to claim 12, wherein the nonvolatile storage unit comprises the memory cell comprising the resistance change element.

21. The resistance change memory according to claim 12, wherein the resistance change element comprises a magnetic tunnel junction (MTJ) element.
